(19) United States
(12) Patent Application Publication
(10) Pub. No.: US 2014/0273887 A1
(43) Pub. Date: Sep. 18, 2014

(54) TUNABLE ILA AND DILA MATCHING FOR SIMULTANEOUS HIGH AND LOW BAND OPERATION

(71) Applicant: MOTOROLA MOBILITY LLC, Libertyville, IL (US)

(72) Inventors: Gregory R. Black, Vernon HIlls, IL (US); Jun S. Zhao, Vernon Hills, IL (US)

(73) Assignee: MOTOROLA MOBILITY LLC, Libertyville, IL (US)

(21) Appl. No.: 14/195,122

(22) Filed: Mar. 3, 2014

Related U.S. Application Data
(60) Provisional application No. 61/788,591, filed on Mar. 15, 2013.

(51) Int. Cl. H03H 7/40; H04B 1/40

(52) U.S. Cl. CPC H03H 7/40; H04B 1/40
USPC 455/77

(57) ABSTRACT

A method and system configures a wireless communication device to support simultaneous signal propagation using a single narrow band antenna. An antenna tuner controller (ATC) configures a tunable low band matching circuit to provide a first antenna matching in order to support propagation of a low band signal with a first signal path. The ATC configures a tunable high band matching circuit to provide a second antenna matching which can support propagation of a high band signal within a second signal path. In addition, the ATC provides isolation between the tunable matching circuits, utilizing a diplexer circuit having a low band component coupled to the first signal path and a high band component coupled to the second signal path. The ATC simultaneously propagates the low and high band signals using a single, shared narrow band antenna coupled to the first and second signal paths.

### BACKGROUND

1. Technical Field

The present disclosure relates in general to wireless communication devices and in particular to antenna matching and isolation in wireless communication devices.

2. Description of the Related Art

Simultaneous signal propagation is a requirement for many communication network operators. While the sizes of wireless communications devices decrease, the challenge of providing high performance signal propagation continues. In addition, wireless communication devices are constantly integrating additional features and capabilities. With limited real estate, designers of wireless communication devices are tasked with optimizing antenna matching and isolation to satisfy specified high performance requirements.

### BRIEF DESCRIPTION OF THE DRAWINGS

The described embodiments are to be read in conjunction with the accompanying drawings, wherein:

FIG. 1 is a block diagram illustrating an example wireless communication device within which the various features of the described embodiments can be advantageously implemented, according to one embodiment;

FIG. 2 is a block diagram of a transceiver module that can be configured to support simultaneous signal propagation via a single antenna, according to one embodiment;

FIG. 3 is a component level illustration of a transceiver module arranged in a first configuration, according to one embodiment;

FIG. 4 is a component level illustration of a transceiver module arranged in a second configuration, according to one embodiment;

FIG. 5 is a component level illustration of a transceiver module arranged in a third configuration, according to one embodiment;

FIG. 6 illustrates a first single Dual Inverted L Antenna (DILA) structure for use within a first wireless communication device that is capable of supporting simultaneous signal propagation, according to one embodiment;

FIG. 7 illustrates a second DILA structure for use within a second wireless communication device that is capable of supporting simultaneous signal propagation, according to one embodiment; and

FIG. 8 is a flow chart illustrating one embodiment of a method for configuring low and high band tunable antenna matching circuits to support simultaneous signal propagation using a single antenna, according to one embodiment.

### DETAILED DESCRIPTION

The illustrative embodiments provide a method and system for configuring a wireless communication device to support simultaneous signal propagation using a single narrow band antenna. An antenna tuner controller (ATC) configures a tunable low band matching circuit to provide a first antenna matching in order to support propagation of a low band signal with a first signal path. The ATC configures a tunable high band matching circuit to provide a second antenna matching which can support propagation of a high band signal within a second signal path. In addition, the ATC provides isolation between the tunable matching circuits, utilizing a diplexer circuit having a low band component coupled to the first signal path and a high band component coupled to the second signal path. The ATC simultaneously propagates the low and high band signals using a single, shared narrow band antenna coupled to the first and second signal paths.

In the following detailed description of exemplary embodiments of the disclosure, specific exemplary embodiments in which the various aspects of the disclosure may be practiced are described in sufficient detail to enable those skilled in the art to practice the invention, and it is to be understood that other embodiments may be utilized and that logical, architectural, programmatic, mechanical, electrical and other changes may be made without departing from the spirit or scope of the present disclosure. The following detailed description is, therefore, not to be taken in a limiting sense, and the scope of the present disclosure is defined by the appended claims and equivalents thereof.

Within the descriptions of the different views of the figures, similar elements are provided similar names and reference numerals as those of the previous figure(s). The specific numerals assigned to the elements are provided solely to aid in the description and are not meant to imply any limitations (structural or functional or otherwise) on the described embodiment.

It is understood that the use of specific component, device and/or parameter names, such as those of the executing utility, logic, and/or firmware described herein, are for example only and not meant to imply any limitations on the described embodiments. The embodiments may thus be described with different nomenclature and/or terminology utilized to describe the components, devices, parameters, methods and/or functions herein, without limitation. References to any specific protocol or proprietary name in describing one or more elements, features or concepts of the embodiments are provided solely as examples of one implementation, and such references do not limit the extension of the claimed embodiments to embodiments in which different element, feature, protocol, or concept names are utilized. Thus, each term utilized herein is to be given its broadest interpretation given the context in which that terms is utilized.

As further described below, implementation of the functional features of the disclosure described herein is provided within processing devices and/or structures and can involve use of a combination of hardware, firmware, as well as several software-level constructs (e.g., program code and/or program instructions and/or pseudo-code) that execute to provide a specific utility for the device or a specific functional logic. The presented figures illustrate both hardware components and software and/or logic components.

Those of ordinary skill in the art will appreciate that the hardware components and basic configurations depicted in the figures may vary. The illustrative components are not intended to be exhaustive, but rather are representative to highlight essential components that are utilized to implement aspects of the described embodiments. For example, other devices/components may be used in addition to or in place of the hardware and/or firmware depicted. The depicted example is not meant to imply architectural or other limitations with respect to the presently described embodiments and/or the general invention.

The description of the illustrative embodiments can be read in conjunction with the accompanying figures. It will be appreciated that for simplicity and clarity of illustration, elements illustrated in the figures have not necessarily been drawn to scale. For example, the dimensions of some of the elements are exaggerated relative to other elements. Embodiments incorporating teachings of the present disclosure are shown and described with respect to the figures presented herein.

With specific reference now to FIG. 1, there is depicted a block diagram of an example wireless communication device 100, within which the functional aspects of the described embodiments may be implemented. Wireless communication device 100 represents a device that is adapted to transmit and receive electromagnetic signals over an air interface via uplink and/or downlink channels between the wireless communication device 100 and communication network equipment (e.g., base-station 145) utilizing a plurality of different communication standards, such as Global System for Mobile Communications (GSM) Code Division Multiple Access (CDMA), Orthogonal Frequency Division Multiple Access (OFDMA), and similar systems. In addition, wireless communication device 100 is able to utilize a number of communication means (e.g., carrier aggregation and simultaneous voice and LTE (SVLTE)) that concurrently enables simultaneous signal propagation. In one or more embodiments, the wireless communication device can be a mobile cellular device/phone or smartphone, or laptop, netbook or tablet computing device, or other types of communications devices. Wireless communication device 100 comprises processor 105 and interface circuitry 125, which are connected to memory component 106 via signal bus 102. Interface circuitry 125 includes digital signal processor (DSP) 128. In addition, wireless communication device 100 comprises storage 122. Also illustrated within wireless communication device 100 are input/output (I/O) devices 129. Wireless communication device 100 also includes a transceiver module 130 for sending and receiving communication signals. In at least some embodiments, the sending and receiving of communication signals occur wirelessly and are facilitated by one or more antennas 140 coupled to transceiver module 130. The number of antennas can vary from device to device, ranging from one or more antennas, and the presentation within wireless communication device 100 of one antenna 140 is merely for illustration.

Wireless communication device 100 is able to wirelessly communicate to base-station 145 via antenna 140. Base station 145 can be any one of a number of different types of network stations and/or antennas associated with the infrastructure of the wireless network and configured to support uplink and downlink communication via one or more of the wireless communication protocols, as known by those skilled in the art.

Transceiver module 130 comprises baseband integrated circuit (BBIC) 133 and radio frequency integrated circuit (RFIC) 132. RFIC 132 comprises a memory or storage system 150. In one embodiment, RFIC 132 also includes local processor 155, which may be described as a digital signal processor (DSP). Transceiver module 130 also comprises antenna system controller 160. In addition, transceiver module 130 comprises first tunable antenna matching circuit (TAMC) 208, second TAMC 228, first transceiver 202 and second transceiver 222. Also included in transceiver module 130 are diplexer circuit 170 and other radio communication components shown in FIG. 2. In one implementation, antenna system controller 160 is communicatively coupled to both tunable antenna matching circuits 208 and 228. According to one aspect of the disclosure, local memory/storage 150 includes therein firmware, such as Antenna Tuner Controller (ATC) utility 167, which supports the various processing functions of transceiver module 130. The structural makeup of transceiver module 130 is described in greater detail in FIG. 2.

In addition to the above described hardware components of wireless communication device 100, various features of the invention may be completed or supported via software or firmware code and/or logic stored within at least one of memory 106 and local memory 150, and respectively executed by DSP 128 or processor 105, or local processor 155 of transceiver module 130. Thus, for example, included within system memory 106 and/or local memory 150 are a number of software, firmware, data logic components, or modules, including applications 116, antenna matching configuration data 114, diplexer configuration data 115 and antenna tuner controller (ATC) utility 167.

The various hardware components within wireless communication device 100 can be electrically and/or communicatively coupled together as illustrated in FIG. 1. As utilized herein, the term “communicatively coupled” means that information signals are transmissible through various interconnections between the components. The interconnections between the components can be direct interconnections that include conductive transmission media, or may be indirect interconnections that include one or more intermediate electrical components. Although certain direct interconnections are illustrated in FIG. 1, it is to be understood that more, fewer or different interconnections may be present in other embodiments.

FIG. 2 provides a block diagram representation of a structural configuration of a transceiver module that can be configured to support simultaneous signal propagation via a single antenna, according to one embodiment. Transceiver module 130 comprises first RF transceiver or low band transceiver 202, which includes first RF transmitter (TX) (not shown) and first RF receiver (RX) (not shown). Transceiver module 130 also comprises first tunable low band antenna matching circuit 208 which is coupled to low band transceiver 202. In addition, transceiver module 130 comprises diplexer circuit 214 which is coupled to first tunable low band antenna matching circuit 208 and to antenna 140 which operates as a narrowband antenna. Diplexer circuit 214 comprises low band component 215 and high band component 235. Transceiver module 130 also comprises antenna tuner controller (ATC) 160 which is coupled to low band transceiver 202, first tunable low band antenna matching circuit 208 and diplexer circuit 214. Low band transceiver 202, first tunable low band antenna matching circuit 208, low band component 215 of diplexer circuit 214 and narrow band antenna 140 collectively represent a first signal path.

In one embodiment, transceiver module 130 utilizes an antenna structure that couples inductors within the antenna structure in order to provide antenna isolation to support simultaneous propagation of low and high band signals. As illustrated, in one embodiment, transceiver module 130 includes at least one of: (a) low and high band diplexer components 215 and 235; and (b) low and high band isolation components 238 coupled within antenna structure 140. In one embodiment, a DILA is coupled to series inductor 680 and shunt inductor 682 (FIG. 6), in order to provide antenna structure 140.

Transceiver module 130 further comprises second RF transceiver or high band transceiver 222, which includes second RF transmitter (TX) (not shown) and second RF receiver (RX) (not shown). Transceiver module 130 also comprises second, tunable high band antenna matching circuit 228 which is coupled to high band transceiver 222 and high band component 235 of diplexer circuit 214. Antenna tuner controller 160 is further coupled to high band transceiver 222 and second tunable high band antenna matching circuit 228. High band transceiver 222, second tunable high band antenna matching circuit 228, high band component 235 of diplexer circuit 214 and narrow band antenna 140 collectively represent a second signal path.

ATC 160 configures transceiver module 130 to support simultaneous signal propagation using single narrow band antenna 140. In particular, ATC 160 configures tunable low band matching circuit 208 coupled within the first signal path to provide a first antenna matching in order to support propagation of a low band signal within a first signal path. ATC 160 configures tunable high band matching circuit 228 coupled within the second signal path to provide a second antenna matching which can support propagation of a high band signal within the second signal path. In addition, ATC 160 provides isolation between tunable matching circuits, utilizing diplexer circuit 214 having low band component 215 coupled to the first signal path and a high band component 235 coupled to the second signal path. Based on the isolation provided, ATC 160 enables the first antenna matching for the first signal path to be provided independently of second antenna matching for the second signal path. ATC 160 simultaneously propagates the low and high band signals using single, shared narrow band antenna 140 coupled to the first and second signal paths.

In one embodiment, ATC 160 retrieves antenna matching configuration data 114 from memory which data ATC 160 utilizes to configure tunable antenna matching circuits 208 and 228. Additionally, ATC 160 retrieves diplexer configuration data 115 which ATC 160 utilizes to configure diplexer circuit 214. In one or more implementations, ATC 160 receives tunable antenna matching and diplexer configuration data 114 and 115 via inputs 221. Low band tunable matching circuit 208 provides the first antenna matching using a complex conjugate impedance match from a low band port of first transceiver 202 to low band component 215 of diplexer circuit 214. High band tunable matching circuit 228 provides the second antenna matching using a complex conjugate impedance match from a high band port of second transceiver 222 to high band component 235 of diplexer circuit 214.

Diplexer circuit 214 provides high band attenuation to reduce low band power dissipation in high band transceiver 222 and provides the first antenna matching independently of a configured state of tunable high band antenna matching circuit 228. In addition, diplexer circuit 214 provides low band attenuation to reduce high band power dissipation in low band transceiver 202 and provides the second antenna matching independently of the configured state of tunable low band antenna matching circuit 208. Furthermore, diplexer circuit 214 provides at least one fixed, partial matching circuit that reduces (a) a maximum voltage standing wave ratio (VSWR) that a corresponding tunable matching circuit has to minimize and (b) at least one tuning range requirement.

In one or more embodiments, ATC 160 determines whether an operating mode that provides simultaneous signal propagation is initiated. If the operating mode that provides simultaneous signal propagation is initiated, ATC 160 configures tunable antenna matching circuits 208 and 228 based on low and high band operating frequencies specified for the operating mode providing simultaneous signal propagation. In addition, ATC 160 configures low and high band diplexer circuit components 215 and 235 to provide antenna isolation to minimize interference that affects signal propagation when wireless communication device 100 actively operates to provide simultaneous signal propagation. As a result of the isolation being provided, ATC 160 is able to provide antenna matching that attains at least one of: (a) a first threshold level of antenna efficiency; (b) a second threshold level of total radiated power (TRP) at a corresponding transmitter; and (c) a third threshold level of total integrated sensitivity (TIS) at a corresponding receiver.

Three different configurations of a transceiver module, such as transceiver module 130, are described using FIGS. 3-5. The functional description of transceiver module 130 similarly applies to the following three configurations of the transceiver module and, in the descriptions that follow, FIGS. 3-5 are primarily described from a structural perspective.

FIG. 3 is a component level illustration of a transceiver module arranged in a first configuration, according to one embodiment. Transceiver module 330 has a substantially identical block level representation to transceiver 130 and is structurally described primarily at a component level. In the first configuration provided by transceiver 330, first tunable low band antenna matching circuit 308 comprises: shunt capacitor 352 coupled to low band transceiver 302; series inductor 354 coupled to shunt capacitor 352 and to low band transceiver 302; and tunable series capacitor 356 coupled to series inductor 354 and to low band component 315 of fixed diplexer circuit 314. Low band component 315 comprises (i) shunt inductor 386 coupled to tunable series capacitor 356 of low band tunable matching circuit 308 and (ii) series inductor 388 coupled to single, shared narrow band antenna 340.

Second, tunable high band antenna matching circuit 338 comprises: first tunable shunt reactance 370 comprising tunable capacitor 372 in parallel with inductor 374 and which is coupled to high band transceiver 322; series inductor 376 coupled to first tunable shunt reactance 370; and second tunable shunt reactance 380 comprising tunable capacitor 382 in parallel with an inductor 384 and which is coupled to high band component 335 of diplexer circuit 314. High band component 335 is implemented using a tunable series capacitor which is coupled to second tunable shunt reactance 380 of high band tunable matching circuit 338 and the single, shared narrow band antenna 340.

FIG. 4 is a component level illustration of a transceiver module, such as transceiver module 130, arranged in a second configuration, according to one embodiment. Transceiver module 430 has a substantially identical block level representation to transceiver 130 and is structurally described primarily at a component level. In the second configuration provided by transceiver 430, first tunable low band antenna matching circuit 408 comprises shunt capacitor 452 coupled to low band transceiver 402, series inductor 454 coupled to shunt capacitor 452 and to low band transceiver 402, and tunable series capacitor 456 coupled to series inductor 454 and to low band component 415 of fixed diplexer circuit 414. Low band component 415 comprises (i) shunt inductor 486 coupled to tunable series capacitor 456 of low band tunable matching circuit 408 and (ii) series inductor 488 coupled to single, shared narrow band antenna 440.

Second, tunable high band antenna matching circuit 428 comprises: first shunt reactance 470 coupled to high band transceiver 422 and comprising (i) first inductor 474 and second inductor 476 connected in parallel and (ii) tunable capacitor 472 connected in parallel with first and second inductors 474 and 476; and tunable series reactance 480 coupled to first shunt reactance 470, high band transceiver 422 and diplexer circuit 414 and comprising inductor 482 and tunable capacitor 484 connected in parallel. High band component 435 comprises shunt inductor 492 and tunable series capacitor 494 coupled to shunt inductor 492.

FIG. 5 is a block diagram illustration of a transceiver module arranged in a third configuration, according to one embodiment. Transceiver module 530 is structurally configured similarly to transceiver module 130 (FIG. 2). However, fixed diplexer circuit 514 provides a different configuration for supporting simultaneous propagation of low and high band signals. Transceiver module 530 comprises an antenna matching circuit which has separate low band and high band connections to the transceiver which comprises low and high band transceivers (not explicitly shown). More specifically, the antenna matching circuit comprises tunable low band matching circuit 508 connected to the low band transceiver via first low band port 504 (of the transceiver) and a tunable high band matching circuit 538 connected to the high band transceiver via second high band port 524. In addition, transceiver module 530 comprises fixed diplexing circuit 514 which is connected to tunable low band matching circuit 508 and tunable high band matching circuit 538. Also coupled to fixed diplexing circuit 514 is antenna 540.

By having separate low band and high band connections to the transceiver, the matching circuit can provide isolation between the low band and the high band signals. In particular, the matching circuit can attenuate harmonics of the low band transmit signal. As a result, the high band receiver can operate simultaneously with the low band transmitter, without being desensitized, even when the high band receive frequency is equal to a low band transmit frequency harmonic which can be coupled from the transceiver via low band port 504 or generated in the tunable low band matching circuit 508. In particular, for low band operation in the 3GPP band 12, having transmit frequencies from 698 to 715 MHz, and high band operation in the 3GPP band 4, having receive operation from 2110 to 2155 MHz, it is important that the third harmonic generated in the of the low band transmit signal path is isolated from the high band receiver.

Fixed diplexer circuit 514 comprises low band component 515 comprising L0, C0, L1 and C1, where L0 and L1 are fixed inductors and C0 and C1 are fixed capacitors. L0 and C0 are arranged to form a parallel resonant circuit, or ‘tank circuit’, connected in series between the antenna and the tunable low band matching circuit, having a resonant frequency of 1/[(2*pi)*(L0*C0){circumflex over ())}{circumflex over (})}0.5]. Below the resonant frequency the tank circuit functions as an inductor, and above the resonant frequency, the tank functions as a capacitor. At the resonant frequency the reactance approaches zero and the tank is approximately an open circuit. The values of L0 and C0 are selected to provide a resonant frequency that is located within the high band receive frequency band. As a result, L0 and C0 function as a matching inductance at the low band frequencies, and as an open circuit at the high band frequencies. L1 and C1 comprise a parallel resonant circuit, or ‘tank circuit’, connected in shunt between the low band matching circuit and ground, having a resonant frequency of 1/[(2*pi)*(L1*C1)̂0.5]. The values of L1 and C1 are selected such that the resonant frequency is a frequency above the low frequency bands and below the high frequency bands. Consequently, L1 and C1 function as a matching inductance at the low band transmit and receive frequencies, and an isolating capacitance at the high band frequencies. The series L-shunt L matching circuit provides a low loss matching circuit for electrically short antennas having input reflection coefficient in the lower half (quadrant 3 and 4) of the Smith chart, which is typically the case for low band operation. Thus, low band component 515 comprising L0, C0, L1, and C1 functions as a series L-shunt L matching circuit in the low bands, and as a series open-shunt C in the high bands for isolation. Importantly, the low band component 515 attenuates harmonics of the low band transmit signal which can couple from the low band signal path, either from low band port 504 or from non-linear components, such as tunable capacitors C1 and C2 in the tunable low band matching circuit 508.

Fixed diplexer circuit 514 also comprises high band component 535 comprising L5, C5, L6 and C6, where L5 and L6 are fixed inductors and C5 and C6 are fixed capacitors. L5 and C5 are arranged to form a parallel resonant circuit, or ‘tank circuit’, connected in series between the antenna and the tunable low band matching circuit, having a resonant frequency of 1/[(2*pi)*(L5*C5)̂0.5]. Below the resonant frequency, the tank circuit functions as an inductor, and above the resonant frequency, the tank circuit functions as a capacitor. At the resonant frequency, the reactance approaches zero, and the tank circuit is approximately and open circuit. The values of L5 and C5 are selected such that the resonant frequency is a frequency in the low band transmit frequency band. As a result, L0 and C0 function as a matching capacitance at the high band frequencies, and as an open circuit at the low band frequencies. L6 and C6 comprise a parallel resonant circuit, or ‘tank circuit’, connected in shunt between the low band matching circuit and ground, having a resonant frequency of 1/[(2*pi)*(L6*C6)̂0.5]. The values of L6 and C6 are selected such that the resonant frequency is a frequency above the low frequency bands and below the high frequency bands. The series C-shunt C matching circuit provides a low loss matching circuit for electrically longer antennas having input reflection coefficient in the upper half (quadrant 1 and 2) of the Smith chart, which is typically the case for high band operation. Thus, the low band side comprising L5, C5, L6, and C6 functions as a series C-shunt C matching circuit in the high bands, and as a series open-shunt L in the low bands for isolation. Importantly, the high band component 535 attenuates the low band transmit signal which can couple from the antenna, and thereby prevents transmit harmonics from being generated in the high band receive path, such as in tunable capacitors C7 and C8 in the tunable high band matching circuit 538.

Tunable low band matching circuit 508 comprises L2, C2, and C3, where L2 is a fixed inductor and C2 and C3 are tunable capacitors. L2 and C2 form a series resonant circuit connected in series, having a resonant frequency of 1/[(2*pi)*(L2*C2)̂0.5]. The value of L2 can be selected such that the resonant frequency is above the low bands. Consequently, the series resonant circuit can function like a tunable series capacitor, albeit with larger tuning range than would be possible from C2 alone. L2 can also be selected such that the resonant frequency is below the low bands and, as a result, the series resonant circuit can function like a tunable series inductor. L2 can be selected such that the resonant frequency is located within the low bands and, as a result, the series resonant circuit can function either as a capacitor or an inductor. C3 is a tunable capacitor in shunt between the low band port and ground. Thus, the tunable low band matching circuit comprises a tunable series X-shunt C circuit, where X is a tunable reactance and C is a tunable capacitance. The tunable values are selected to provide maximum delivered power from the low band port to the antenna for transmit operation, and from the antenna to the low band port for receive operation.

Tunable high band matching circuit 538 comprises C7, C8, and L8, where C7 and C8 are tunable capacitors, and L8 is a fixed inductor. C7 is a tunable capacitor in series between the fixed diplexer and the high band port. L8 and C8 form a parallel resonant circuit connected in shunt, having a resonant frequency of 1/[(2*pi)*(L8*C8)̂0.5]. The value of L8 can be selected such that the resonant frequency is above the high bands. As a result, the series resonant circuit can function like a tunable shunt capacitor, albeit with larger tuning range than would be possible from C8 alone. L2 can also be selected such that the resonant frequency is below the high bands and, as a result, the series resonant circuit can function like a tunable shunt inductor. L2 can be selected such that the resonant frequency is in the high bands. Therefore, the parallel resonant circuit can function either as a capacitor or an inductor. Thus, the tunable low band matching circuit comprises a tunable series C-shunt X circuit, where C is a tunable capacitance and X is a tunable reactance. The tunable values are selected to provide maximum delivered power from the high band port to the antenna for transmit operation, and from the antenna to the high band port for receive operation.

FIGS. 6 and 7 respectively show a first single Dual Inverted L Antenna (DILA) structure for use within a first wireless communication device and which is capable of supporting simultaneous signal propagation and a second Dual Inverted L Antenna (DILA) structure for use within a second wireless communication device. Second antenna structure 650 includes components of a fixed duplexer and can support simultaneous signal propagation, according to one embodiment. Three views of first antenna structure 610 are provided. Front view 630 shows housing 636 bordering circuit board 632 on which antenna 634 is affixed. Antenna 634 consists of one or more radiating elements constructed of highly conductive material such as copper metal, or metal plated material. Side view 620 and first bottom view 640 respectively provide different views of antenna 634. In one embodiment, antenna 634 is a DILA.

Three views of second antenna structure 650 are provided. Front view 670 shows housing 676 bordering circuit board 672 on which antenna 674 is affixed. Side view 660 and bottom view 690 respectively provide different views of antenna 674. Antenna 674 represents an antenna structure in which diplexer functionality by use of at least one corresponding circuit component is integrated into an antenna to provide antenna 674. Antenna 674 is substantially identical to antennas 340, 440 and 540 which are implemented within the first, second and third configurations of a transceiver module (e.g., transceiver modules 330, 430 and 530 of FIGS. 3, 4 and 5, respectively). Antenna 674 is designed by integrating series inductor 680 and shunt inductor 682 which can replace series and shunt inductors in the transceiver modules. Advantageously, inductors 680 and 682 can be formed by meander lines comprising the same materials constructing the antenna radiating arms 674. In particular, series meander line 680 can replace series inductor 388 (FIG. 3), series inductor 488 (FIG. 4) and series inductor L0 of element 515 (FIG. 5). Similarly shunt meander line 682 can replace shunt inductor 386 (FIG. 3), shunt inductor 486 (FIG. 4) and shunt inductor L1 of element 515 (FIG. 5). In one embodiment, antenna 674 is a DILA integrated with diplexer functionality and circuit components.

Observation of the different views of first and second antenna structures 610 and 650 indicates that side views 620 and 660 are substantially identical. Thus, wireless communication device can maintain device width even as antenna 674 is integrated with the diplexer functionality. However, first front view 630 and second front view 670 enables a viewer to detect that antenna 674 is integrated with series inductor 680 and matching shunt inductor 682. Similarly, first bottom view 640 and second bottom view 690 enables a viewer to detect that antenna 674 is integrated with series inductor 680 and matching shunt inductor 682. The bottom views also indicate that wireless communication device 100 can implement antenna 674 without requiring an increase in device thickness. More importantly, based on the observed views, one can conclude that antenna 674 can be implemented without requiring any substantial increase in the use of device real estate.

FIG. 8 is a flow chart illustrating an embodiment of the method by which the above processes of the illustrative embodiments can be implemented. Specifically, FIG. 8 illustrates one embodiment of a method for configuring low and high band tunable antenna matching circuits to support simultaneous signal propagation using a single narrowband antenna. Although the method illustrated by FIG. 8 may be described with reference to components and functionality illustrated by and described in reference to FIGS. 1-7, it should be understood that this is merely for convenience and alternative components and/or configurations thereof can be employed when implementing the method. Certain portions of the methods may be completed by ATC utility 167 executing on one or more processors (processor 105 or DSP 128) within wireless communication device 100 (FIG. 1) or a processing unit or antenna tuner controller 160 (FIG. 1). The executed processes then control specific operations of or within transceiver module 130. For simplicity in describing the method, all method processes are described from the perspective of antenna tuner controller 160.

The method of FIG. 8 begins at initiator block 801 and proceeds to block 802 at which antenna tuner controller (ATC) 160 configures low band tunable matching circuit 208 to provide a first antenna matching in order to propagate a low band signal. AT controller 160 configures a high band tunable matching circuit (210) to provide a second antenna matching in order to propagate a high band signal (block 804). AT controller 160 provides isolation between low band and high band circuit components, utilizing fixed diplexer circuit 214 (block 806). AT controller 160 simultaneously propagates low and high band signals using a single, shared narrow band antenna 140 (block 808). The process ends at block 810.

The flowchart and block diagrams in the various figures presented and described herein illustrate the architecture, functionality, and operation of possible implementations of systems, methods and computer program products according to various embodiments of the present disclosure. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. Thus, while the method processes are described and illustrated in a particular sequence, use of a specific sequence of processes is not meant to imply any limitations on the disclosure. Changes may be made with regards to the sequence of processes without departing from the spirit or scope of the present disclosure. Use of a particular sequence is therefore, not to be taken in a limiting sense, and the scope of the present disclosure extends to the appended claims and equivalents thereof.

In some implementations, certain processes of the methods are combined, performed simultaneously or in a different order, or perhaps omitted, without deviating from the spirit and scope of the disclosure. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

While the disclosure has been described with reference to exemplary embodiments, it will be understood by those skilled in the art that various changes may be made and equivalents may be substituted for elements thereof without departing from the scope of the disclosure. In addition, many modifications may be made to adapt a particular system, device or component thereof to the teachings of the disclosure without departing from the essential scope thereof. Therefore, it is intended that the disclosure not be limited to the particular embodiments disclosed for carrying out this disclosure, but that the disclosure will include all embodiments falling within the scope of the appended claims. Moreover, the use of the terms first, second, etc. do not denote any order or importance, but rather the terms first, second, etc. are used to distinguish one element from another.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A wireless communication device comprising:
a transceiver module coupled to at least one antenna and which includes:
at least one processor;
at least two transceivers including a first transceiver coupled to a first signal path and a second transceiver coupled to a second signal path, wherein the first and second signal paths are coupled to a single, shared narrow band antenna;
a low band tunable matching circuit coupled within the first signal path to the first transceiver;
a high band tunable matching circuit coupled within the second signal path to the second transceiver;
a diplexer circuit coupled to the low band tunable matching circuit and to the high band tunable matching circuit and which provides isolation between low band and high band tunable matching circuits, utilizing diplexer circuit components respectively coupled to the first and second signal paths;
an antenna tuner controller that:
configures (a) the low band tunable matching circuit to provide a first antenna matching corresponding to a low band operating frequency to support propagation of a low band signal and (b) the high band tunable matching circuit to provide a second antenna matching corresponding to a high band operating frequency to support propagation of a high band signal;
configures the diplexer circuit to provide a specified isolation between low band tunable matching circuit components and high band circuit components, enabling the first antenna matching to be provided independently of the second antenna matching; and
provides, using the single, shared narrow band antenna, simultaneous propagation of the low band signal and the high band signal.

2. The wireless communication device of claim 1, wherein:
the low band tunable matching circuit provides the first antenna matching using a complex conjugate impedance match from a low band port of the first transceiver to a low band component of the diplexer circuit; and
the high band tunable matching circuit provides the second antenna matching using a complex conjugate impedance match from a high band port of the second transceiver to a high band component of the diplexer circuit.

3. The wireless communication device of claim 1, wherein the low band tunable matching circuit further comprises:
a shunt capacitor coupled to the first transceiver;
a series inductor coupled to the shunt capacitor and to the first transceiver; and
a tunable series capacitor coupled to the series inductor and to the fixed diplexer circuit.

4. The wireless communication device of claim 3, wherein the high band tunable matching circuit comprises:
a first tunable shunt reactance comprising a tunable capacitor in parallel with an inductor and which is coupled to the second transceiver;
a series inductor coupled to the first tunable shunt reactance; and
a second tunable shunt reactance comprising a tunable capacitor in parallel with an inductor and which is coupled to the fixed diplexer circuit.

5. The wireless communication device of claim 1, wherein the diplexer circuit comprises:
a low band diplexer sub-circuit component coupled within the low band signal path and which includes (i) a shunt inductor coupled to the low band tunable matching circuit and (ii) a series inductor coupled to the single, shared narrow band antenna; and
a high band diplexer sub-circuit component coupled within the high band signal path and which includes a series capacitor coupled to the high band tunable matching circuit and the single, shared narrow band antenna.

6. The wireless communication device of claim 5, wherein the low band diplexer sub-circuit further comprises a series capacitor, coupled to the single, shared narrow band antenna, wherein the series inductor and the series capacitor of the low band diplexer sub-circuit have a resonant frequency equal to a harmonic of a low band transmission frequency.

7. The wireless communication device of claim 5, wherein the high band diplexer sub-circuit further comprises a series inductor coupled to the single, shared narrow band antenna, wherein the series inductor and the series capacitor of the high band diplexer sub-circuit have a resonant frequency equal to a low band transmission frequency.

8. The wireless communication device of claim 1, wherein the low band tunable matching circuit further comprises:
a shunt capacitor coupled to the first transceiver;
a series inductor coupled to the shunt capacitor and to the first transceiver; and
a tunable series capacitor coupled to the series inductor and to the diplexer circuit.

9. The wireless communication device of claim 8, wherein the high band tunable matching circuit comprises:
a first shunt reactance coupled to the second transceiver and comprising (i) a first inductor and a second inductor connected in parallel and (ii) a tunable capacitor connected in parallel with the first and second inductors; and
a tunable series reactance coupled to the first shunt reactance, the second transceiver and the diplexer circuit and comprising an inductor and a tunable capacitor connected in parallel.

10. The wireless communication device of claim 1, wherein the at least one antenna comprises:
at least one radiating element; and
at least one diplexing component coupled to the radiating element and the low band tunable matching circuit and providing isolation between low band and high band tunable matching circuits and which comprises a meander line constructed from a same material as the radiating element.

11. The wireless communication device of claim 1, wherein the diplexer circuit: provides high band attenuation to reduce low band power dissipation in the high band transceiver and provides the first antenna matching independently of a configured state of the tunable high band antenna matching circuit; provides low band attenuation to reduce high band power dissipation in the low band transceiver and provides the second antenna matching independently of the configured state of the tunable low band antenna matching circuit; and provides at least one partial matching circuit that reduces (a) a maximum voltage standing wave ratio (VSWR) that a corresponding tunable matching circuit has to minimize and (b) at least one tuning range requirement.

12. In a wireless communication device, a transceiver module coupled to at least one antenna, the transceiver module comprising:
at least one processor;
at least two transceivers including a first transceiver coupled to a first signal path and a second transceiver coupled to a second signal path, wherein the first and second signal paths are coupled to a single, shared narrow band antenna;
a low band tunable matching circuit coupled within the first signal path to the first transceiver;
a high band tunable matching circuit coupled within the second signal path to the second transceiver;
a diplexer circuit coupled to the low band tunable matching circuit and to the high band tunable matching circuit and which provides isolation between low band and high band tunable matching circuits, utilizing diplexer circuit components respectively coupled to the first and second signal paths;
an antenna tuner controller that:
configures (a) the low band tunable matching circuit to provide a first antenna matching corresponding to a low band operating frequency to support propagation of a low band signal and (b) the high band tunable matching circuit to provide a second antenna matching corresponding to a high band operating frequency to support propagation of a high band signal;
configures the diplexer circuit to provide a specified isolation between low band tunable matching circuit components and high band circuit components, enabling the first antenna matching to be provided independently of the second antenna matching; and
provides, using the single, shared narrow band antenna, simultaneous propagation of the low band signal and the high band signal.

13. The transceiver module of claim 12, wherein:
the low band tunable matching circuit provides the first antenna matching using a complex conjugate impedance match from a low band port of the first transceiver to a low band component of the diplexer circuit; and
the high band tunable matching circuit provides the second antenna matching using a complex conjugate impedance match from a high band port of the second transceiver to a high band component of the diplexer circuit.

14. The transceiver module of claim 12, wherein:
the low band tunable matching circuit further comprises: a shunt capacitor coupled to the first transceiver; a series inductor coupled to the shunt capacitor and to the first transceiver; and a tunable series capacitor coupled to the series inductor and to the fixed diplexer circuit;
the high band tunable matching circuit comprises: a first tunable shunt reactance comprising a tunable capacitor in parallel with an inductor and which is coupled to the second transceiver; a series inductor coupled to the first tunable shunt reactance; and a second tunable shunt reactance comprising a tunable capacitor in parallel with an inductor and which is coupled to the fixed diplexer circuit; and
the diplexer circuit further comprises: a low band diplexer sub-circuit component coupled within the low band signal path and which includes (i) a shunt inductor coupled to the low band tunable matching circuit and (ii) a series inductor coupled to the single, shared narrow band antenna; and a high band circuit component coupled within the high band signal path and which includes a series capacitor coupled to the high band tunable matching circuit and the single, shared narrow band antenna.

15. The transceiver module of claim 12, wherein:
the low band tunable matching circuit comprises: a shunt capacitor coupled to the first transceiver; a series inductor coupled to the shunt capacitor and to the first transceiver; and a tunable series capacitor coupled to the series inductor and to the diplexer circuit;
the high band tunable matching circuit comprises: a first shunt reactance coupled to the second transceiver and comprising (i) a first inductor and a second inductor connected in parallel and (ii) a tunable capacitor connected in parallel with the first and second inductors; a tunable series reactance coupled to the first shunt reactance, the second transceiver and the diplexer circuit and comprising an inductor and a tunable capacitor connected in parallel; and
the diplexer circuit is coupled to the single, shared narrow band antenna and comprises: a low band diplexer sub-circuit having (i) a shunt inductor (ii) a series inductor coupled to the shunt inductor and (iii) a series capacitor, coupled to the single, shared narrow band antenna, wherein the series inductor and the series capacitor of the low band diplexer sub-circuit have a resonant frequency equal to a harmonic of a low band transmission frequency; and a high band diplexer sub-circuit coupled to the low band diplexer sub-circuit and having a shunt inductor, a tunable series capacitor coupled to the shunt inductor and a series inductor, coupled to the single, shared narrow band antenna, wherein the series inductor and tunable series capacitor of the high band diplexer sub-circuit have a resonant frequency equal to a low band transmission frequency.

16. The transceiver module of claim 12, wherein the at least one antenna comprises:
at least one radiating element; and
at least one diplexing component coupled to the radiating element and the low band tunable matching circuit and providing isolation between low band and high band tunable matching circuits and which comprises a meander line constructed from a same material as the radiating element.

17. The transceiver module of claim 12, wherein the diplexer circuit: provides high band attenuation to reduce low band power dissipation in the high band transceiver and provides the first antenna matching independently of a configured state of the tunable high band antenna matching circuit; provides low band attenuation to reduce high band power dissipation in the low band transceiver and provides the second antenna matching independently of the configured state of the tunable low band antenna matching circuit; and provides at least one partial matching circuit that reduces (a) a maximum voltage standing wave ratio (VSWR) that a corresponding tunable matching circuit has to minimize and (b) at least one tuning range requirement.

18. A method for configuring an antenna system for simultaneous signal propagation via multiple frequency bands in a wireless communication device, the method comprising:
providing a first antenna matching to support propagation of a low band signal within a first signal path by utilizing a low band tunable matching circuit coupled within the first signal path;
providing a second antenna matching for propagation of a high band signal within a second signal path by utilizing a high band tunable matching circuit coupled within the second signal path;
providing isolation between low band and high band circuit components, utilizing a fixed diplexer circuit coupled to the first and second signal paths, which enables the first antenna matching for the first signal path to be provided independently of second antenna matching for the second signal path; and
simultaneously propagating the low band signal and the high band signal using corresponding signal paths coupled to a single, shared narrow band antenna.

19. The method of claim 18, wherein:
the low band tunable matching circuit provides the first antenna matching using a complex conjugate impedance match from a low band port of the first transceiver to a low band component of the diplexer circuit; and
the high band tunable matching circuit provides the second antenna matching using a complex conjugate impedance match from a high band port of the second transceiver to a high band component of the diplexer circuit.

20. The method of claim 18, wherein the diplexer circuit: provides high band attenuation to reduce low band power dissipation in the high band transceiver and provides the first antenna matching independently of a configured state of the tunable high band antenna matching circuit; provides low band attenuation to reduce high band power dissipation in the low band transceiver and provides the second antenna matching independently of the configured state of the tunable low band antenna matching circuit; and provides at least one partial matching circuit that reduces (a) a maximum voltage standing wave ratio (VSWR) that a corresponding tunable matching circuit has to minimize and (b) at least one tuning range requirement.
